(19) United States
(12) Patent Application Publication
(10) Pub. No.: US 2015/0062460 A1
(43) Pub. Date: Mar. 5, 2015

(54) MOBILE TERMINAL AND METHOD FOR MANUFACTURING THE SAME

(71) Applicant: Sharp Kabushiki kaisha, Osaka-shi, Osaka (JP)

(72) Inventor: Satoshi Yamada, Osaka-shi (JP)

(73) Assignee: SHARP KABUSHIKI KAISHA, Osaka-shi, Osaka (JP)

(21) Appl. No.: 14/389,897

(22) PCT Filed: May 8, 2013
(86) PCT No.: PCT/JP2013/002969

§ 371 Date: Oct. 1, 2014

(30) Foreign Application Priority Data
May 14, 2012 (JP) 2012-110400

(51) Int. Cl. G06F 1/16; H05K 5/03; B29C 70/76

(52) U.S. Cl. CPC G06F 1/1643; B29C 70/763; G06F 1/1626; G06F 1/1656; H05K 5/03; B29L 2031/3475
USPC 349/12; 264/279

(57) ABSTRACT

In a mobile terminal and the method for manufacturing the mobile terminal, the bonding strength between a glass panel and a resin housing is ensured, as well as ensuring as large display area as possible. The width of a touch panel 4 is set greater than that of a glass panel 3, and insert molding is performed such that a corner space 7 formed between a protruding part of the touch panel 4 and a side surface of the glass panel 3 is covered by resin 14 forming a housing 2 in the state in which the touch panel 4 is bonded to a rear surface of the glass panel 3.

### TECHNICAL FIELD

The present invention relates to a mobile terminal including a glass panel and a touch panel provided on a rear side of the glass panel and to the method for manufacturing the mobile terminal.

### BACKGROUND ART

Conventionally, mobile terminals each including a glass panel and a touch panel provided on a rear side of the glass panel have been known. Referring to, e.g., an example illustrated in FIG. 11, in a mobile terminal device 101 of Patent Document 1, a design panel 103 whose rear surface is bonded to a touch panel 104 is fitted into a frame-shaped recessed part 107 on a front side of a housing 102. In the mobile terminal device 101 of this type, the width of the design panel 103 is greater than that of the touch panel 104, and a protruding part of the design panel 103 is, with a double-sided tape 109, an adhesive, etc., bonded to a frame-shaped part of the recessed part 107 of the housing 102.

### CITATION LIST

### Patent Document

PATENT DOCUMENT 1: Japanese Unexamined Patent Publication No. 2010-239324 (particularly see FIG. 4)

### SUMMARY OF THE INVENTION

### Technical Problem

It is desirable to ensure as large display area A as possible. However, since there is a clearance C between a side wall of the recessed part 107 and a side surface of the design panel 103 in the conventional mobile terminal device 101, sufficient waterproof properties should be ensured by, e.g., the double-sided tape 109. Thus, in the case where, e.g., the area (width) of the double-sided tape 109 with which the design panel 103 is bonded to the housing 102 is small, there are disadvantages that the bonding strength of the double-sided tape 109 to the housing 102 becomes lower and that the waterproof properties cannot be ensured.

In order to bond a touch panel to a rear surface of a glass panel, the glass panel bonded to the touch panel may be integrally molded with a housing. However, in this case, it is also necessary to print an adhesive on the rear surface of the glass panel to ensure adhesiveness. Without a certain adhesive printing area, bonding strength cannot be ensured, and a wiring part of the touch panel cannot be sufficiently covered by the adhesive printing area. For such reasons, there is still a disadvantage that a large display area cannot be ensured.

The present invention has been made in view of the foregoing, and is intended to ensure as large display area as possible and ensure the strength of bonding between a glass panel and a resin housing.

### Solution to the Problem

According to the present invention, in order to accomplish the foregoing, when insert molding is performed for a glass panel bonded to a touch panel, resin is inserted into a corner space formed between the touch panel and the glass panel.

Specifically, a first aspect of the invention is intended for a mobile terminal including a glass panel and a touch panel provided on a rear side of the glass panel. The width of the touch panel is greater than that of the glass panel. In the state in which the touch panel is bonded to a rear surface of the glass panel, the touch panel and the glass panel are integrally molded with a housing such that a corner space formed between a protruding part of the touch panel and a side surface of the glass panel is covered by resin forming the housing.

According to the foregoing configuration, the resin is, by insert molding, injected into the corner space formed between the glass panel and the touch panel bonded to the rear surface of the glass panel and having a larger width. A wedge effect exhibited by the resin to exhibit a wedge effect allows the glass panel not to be easily detached due to drop impact and torsional load. Moreover, since the wedge effect improves strength, a large bonding region required in conventional cases is not necessary, and a display area can be expanded.

A second aspect of the invention is intended for the mobile terminal of the first aspect of the invention, in which the resin covering the corner space and a touch panel wiring area overlap with each other as viewed from front.

That is, although the touch panel wiring area should be positioned outside the display area, the touch panel wiring area can be, according to the foregoing configuration, positioned at the space formed on the rear side of the area where the corner space is covered by the resin, and therefore the display area can be further expanded.

A third aspect of the invention is intended for the mobile terminal of the first or second aspect of the invention, in which a transparent optical adhesive tape bonding the touch panel to the rear surface of the glass panel is extended to the protruding part of the touch panel, and is bonded to the resin.

According to the foregoing configuration, since the resin and the touch panel are also bonded together with the transparent optical adhesive tape at the corner space, not only bonding strength is further improved, but also the flexibility of the transparent optical adhesive tape significantly improves a waterproof effect. Thus, bonding strength and waterproof properties can be ensured even if a bonding area between the corner space and the resin is narrowed due to expansion of the display area.

A fourth aspect of the invention is intended for the mobile terminal of any one of the first to third aspects of the invention, in which the length of the touch panel is greater than that of the glass panel, and the touch panel and the glass panel are integrally molded with the housing such that a corner space formed between part of the touch panel protruding in a length direction and the side surface of the glass panel is also covered by the resin forming the housing.

According to the foregoing configuration, the resin exhibits the wedge effect not only in a width direction but also in a longitudinal direction, thereby further increasing the strength and expanding the display area.

A fifth aspect of the invention is intended for the mobile terminal of any one of the first to fourth aspects of the invention, in which the touch panel further includes a glass plate, and the ratio of the thickness of the glass plate to the thickness of the glass panel is about 1:1.

According to the foregoing configuration, since a load applied to the housing is equally distributed to the glass panel and the touch panel, the strength is improved. Note that a ratio of about 1:1 means not only that the thickness of the glass plate and the thickness of the glass panel are completely equal to each other, but also that one of the thickness of the glass plate or the thickness of the glass panel is, to a certain degree, greater than the other one of the thickness of the glass plate or the thickness of the glass panel.

A sixth aspect of the invention is intended for the mobile terminal of any one of the first to fifth aspects of the invention, in which the ratio of the length of the protruding part of the touch panel to the thickness of the glass panel is about 1:1.

According to the foregoing configuration, since a load applied to the housing is equally distributed to the glass panel and the touch panel, the strength is improved. Note that a ratio of about 1:1 means not only that the length of the protruding part of the touch panel and the thickness of the glass panel are completely equal to each other, but also that one of the length of the protruding part of the touch panel or the thickness of the glass panel is, to a certain degree, greater than the other one of the length of the protruding part of the touch panel or the thickness of the glass panel.

A seventh aspect of the invention is intended for the method for manufacturing a mobile terminal including a touch panel on a rear side of a glass panel, which includes a preparation step of preparing the glass panel and the touch panel having a width greater than that of the glass panel; a bonding step of bonding the touch panel to a rear surface of the glass panel; and an insert molding step of mounting the glass panel bonded to the touch panel on a mold, inserting resin into a corner space formed between a protruding part of the touch panel and a side surface of the glass panel, and insert-molding a housing out of the resin.

According to the foregoing configuration, the resin is, by insert molding, injected into the corner space formed between the glass panel and the touch panel bonded to the rear surface of the glass panel and having a larger width. Such a simple method allows the resin to exhibit a wedge effect, and therefore the glass panel is not easily detached due to drop impact and torsional load. Moreover, since the wedge effect improves strength, a large bonding region required in conventional cases is not necessary, and a display area can be expanded.

### Advantages of the Invention

As described above, according to the present invention, the width of the touch panel is set greater than that of the glass panel, and the touch panel and the glass panel are integrally formed with the housing such that the corner space formed between the protruding part of the touch panel and the side surface of the glass panel is covered by the resin forming the housing in the state in which the touch panel is bonded to the rear surface of the glass panel. Thus, while ensuring as large display area as possible without increasing the outer size of the terminal, the bonding strength between the glass panel and the resin housing and waterproof properties can be ensured.

### BRIEF DESCRIPTION OF THE DRAWINGS

FIG. 1 is an enlarged cross-sectional view along an I-I line of FIG. 2.

FIG. 2 is a front view of a mobile phone of an embodiment of the present invention.

FIGS. 3A and 3B illustrate a bonding step in the method for manufacturing the mobile phone. FIG. 3A is a cross-sectional view before bonding. FIG. 3B is a cross-sectional view after bonding.

FIG. 4 is a cross-sectional view illustrating the state in which a glass panel and a touch panel are mounted on a mold after the bonding step.

FIG. 5 is a cross-sectional view illustrating an injection step.

FIG. 6 is a view illustrating the state in which injection is completed.

FIG. 7 is a cross-sectional view illustrating a mold detaching step.

FIG. 8 is a cross-sectional view illustrating the step of bonding, after insert molding, a liquid crystal display is bonded to a rear surface of the touch panel.

FIGS. 9A to 9C are front views illustrating variations in dimensions of a glass panel and a touch panel. FIG. 9A illustrates an example of the dimensions in the embodiment. FIG. 9B illustrates a first variation in which the dimensions are the same as each other on an upper side. FIG. 9C illustrates a second variation in which the dimensions are the same as each other on upper and lower sides.

FIG. 10 is a view illustrating a second embodiment and corresponding to FIG. 1.

FIG. 11 is a view illustrating a prior art and corresponding to FIG. 1.

### DESCRIPTION OF EMBODIMENTS

Embodiments of the present invention will be described below with reference to drawings.

### First Embodiment

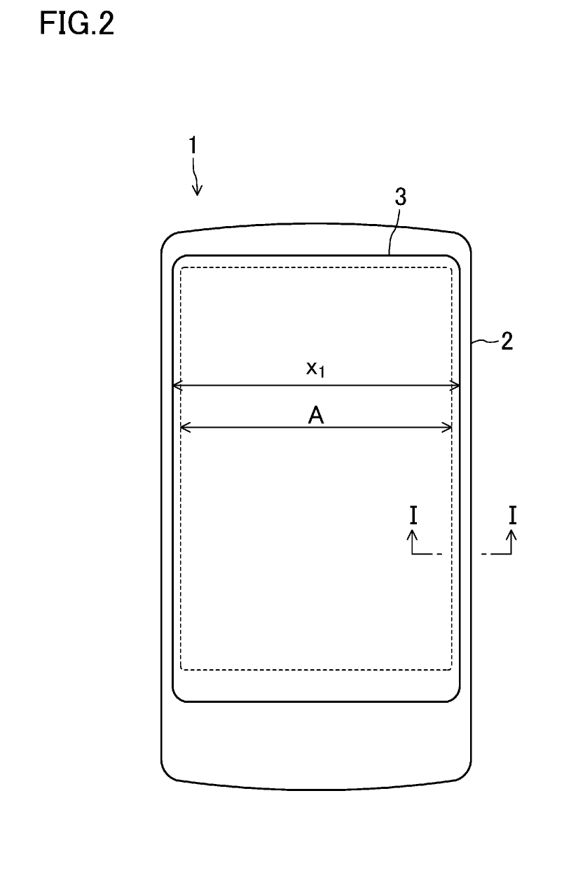

FIG. 2 illustrates a mobile phone 1 serving as a mobile terminal of a first embodiment of the present invention. The mobile phone 1 includes a resin housing 2 formed in a rectangular plate shape.

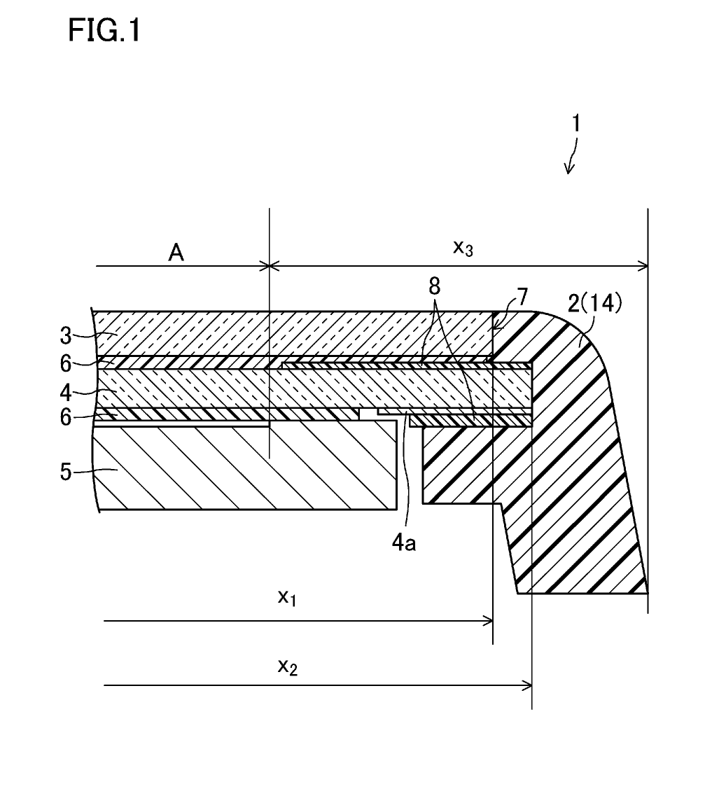

Referring to FIG. 1, the mobile phone 1 includes a rectangular glass panel 3 provided on a front side of the housing 2, and a touch panel 4 having a glass plate bonded to a rear side of the glass panel 3. A liquid crystal display 5 is bonded to a rear surface of the touch panel 4.

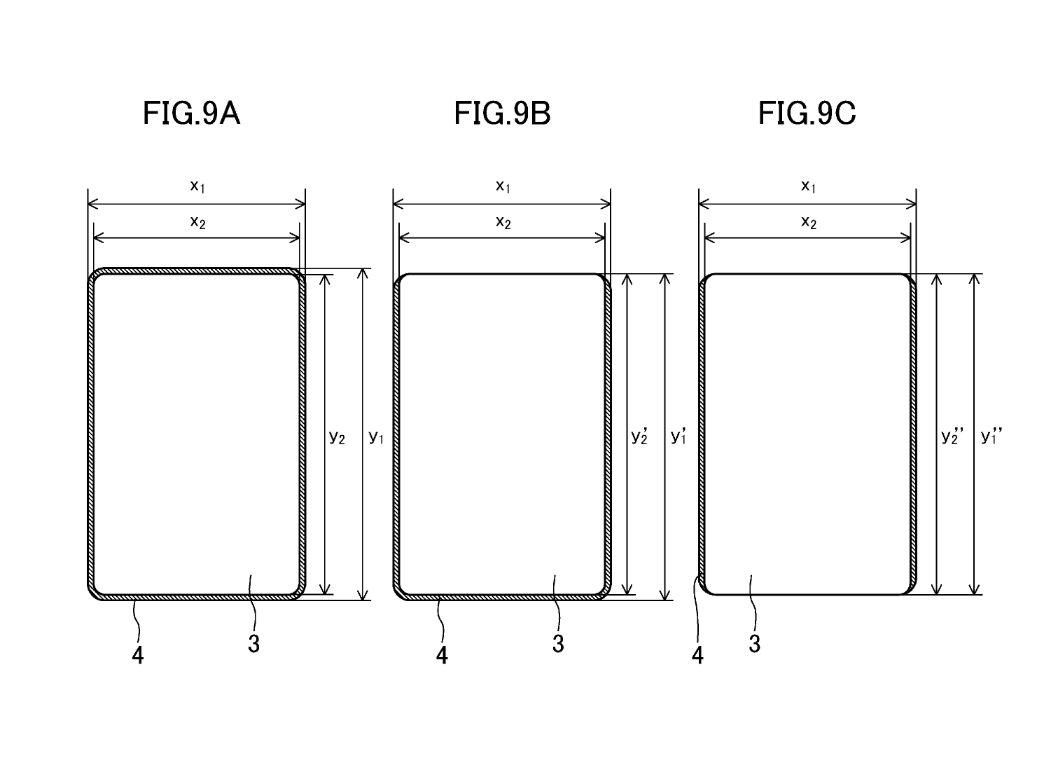

Specifically, in the mobile phone 1 of the present embodiment, the horizontal width x1 of the touch panel 4 is, referring to FIG. 9A, greater than the horizontal width x2 of the glass panel 3 (x1>x2). Moreover, the vertical length y1 of the touch panel 4 is greater than the vertical length y2 of the glass panel 3 (y1>y2). The touch panel 4 and the glass panel 3 are bonded together with a frame-shaped transparent optical adhesive tape 6 bonded to substantially the entirety of a surface of the touch panel 4. The transparent optical adhesive tape 6 is an acrylic-based adhesive material such as an optical clear adhesive (OCA) tape having a thickness of 0.1 to 0.2 mm, and has extremely-high transparency and a moderate degree of flexibility.

In the state in which the touch panel 4 is bonded to the rear surface of the glass panel 3 with the transparent optical adhesive tape 6, a corner space 7 is formed between each of right and left protruding parts of the touch panel 4 and a side surface of the glass panel 3. Such right and left corner spaces 7 are covered by resin forming the housing 2. In the present embodiment, a corner space 7 is also formed between each of upper and lower protruding parts of the touch panel 4 and the side surface of the glass panel 3 as described above. The upper and lower corner spaces 7 are also covered by resin forming the housing 2. An upper surface of the housing 2 and an upper surface of the glass panel 3 are at the same height, and therefore the upper surfaces of the housing 2 and the glass panel 3 are continuous to each other. Thus, since a clearance C formed in conventional cases is not formed, dust is not accumulated in the clearance C, and the appearance of the mobile phone 1 is not degraded.

The touch panel 4 also includes the glass plate. The ratio of the thickness of such a glass plate to the thickness of the glass panel 3 is about 1:1, and such thicknesses are, e.g., about 0.5 mm. Note that a ratio of about 1:1 means not only that the thickness of the glass plate is completely equal to the thickness of the glass panel 3, but also that the thickness of one of the glass plate or the glass panel 3 may be, to a certain degree, greater than the other one of the glass plate or the glass panel 3. A sufficient thickness of the touch panel 4 is 0.2 mm under normal circumstances. However, the thickness of the touch panel 4 is intentionally increased to distribute a load applied to the housing 2 equally to the glass panel 3 and the touch panel 4. Thus, strength is improved.

Moreover, the ratio of the length of the protruding part of the touch panel 4 to the thickness of the glass panel 3 is about 1:1. For example, the length of the protruding part of the touch panel 4 is about 0.5 mm which is equal to the thickness of the glass panel 3. Note that a ratio of about 1:1 means not only that the length of the protruding part of the touch panel 4 is completely equal to the thickness of the glass panel 3, but also one of the length of the protruding part of the touch panel 4 or the thickness of the glass panel 3 may be, to a certain degree, greater than the other one of the length of the protruding part of the touch panel 4 or the thickness of the glass panel 3. That is, there is a possibility that an extremely-large length of the protruding part of the touch panel 4 causes deviation of force applied to the housing 2 to the side close to the touch panel 4 and damages the touch panel 4, but a load is distributed equally to the glass panel 3 and the touch panel 4 in such a manner that the length of the protruding part of the touch panel 4 is set substantially equal to the thickness of the glass panel 3.

The touch panel 4 further includes a touch panel wiring area 4a formed of a transparent conductive member such as an indium oxide (ITO) film. However, in the present embodiment, resin covering the corner space 7 and the touch panel wiring area 4a partially overlap, referring to FIG. 1, with each other as viewed from the front. As just described, since the touch panel wiring area 4a can be positioned at the space formed on the rear side of the area where the corner space 7 is covered by resin, the width x3 of a frame part can be decreased to further expand the display area A.

Next, the method for manufacturing the mobile phone 1 according to the present embodiment will be described.

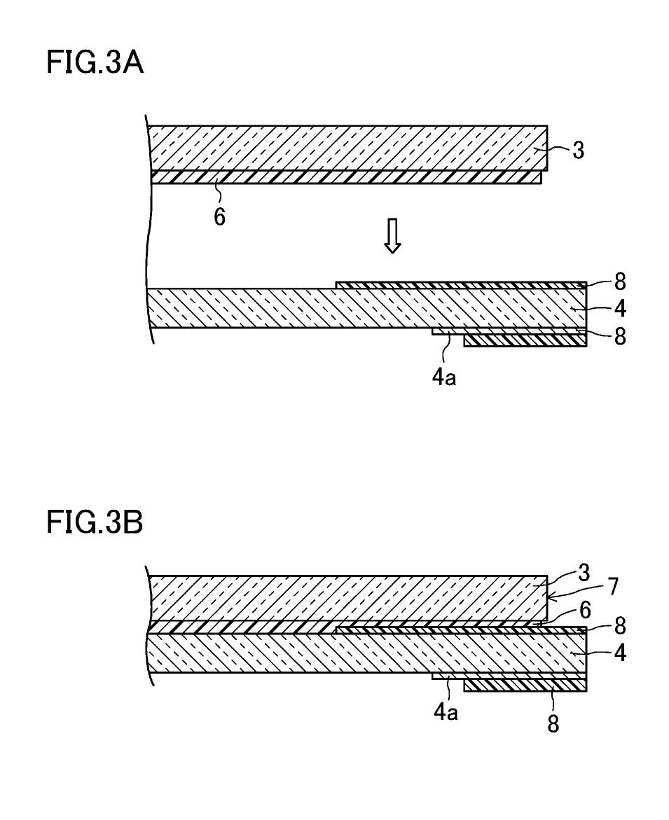

First, at a preparation step, a glass panel 3 cut into a plate shape is prepared as illustrated in FIG. 3A. At this step, a transparent optical adhesive tape 6 may be, at one surface thereof, bonded to a rear surface of the glass panel 3. A decorative-printed coat 8 containing an adhesive is formed on part of front and rear surfaces of a touch panel 4 including a touch panel wiring area 4a. For example, a black aqueous acrylic emulsion adhesive is used for the decorative-printed coat 8. The width of the decorative-printed coat 8 is greater on a front side than on a rear side.

Next, at a bonding step illustrated in FIGS. 3A and 3B, the touch panel 4 is bonded to the glass panel 3 whose rear surface is bonded to the transparent optical adhesive tape 6.

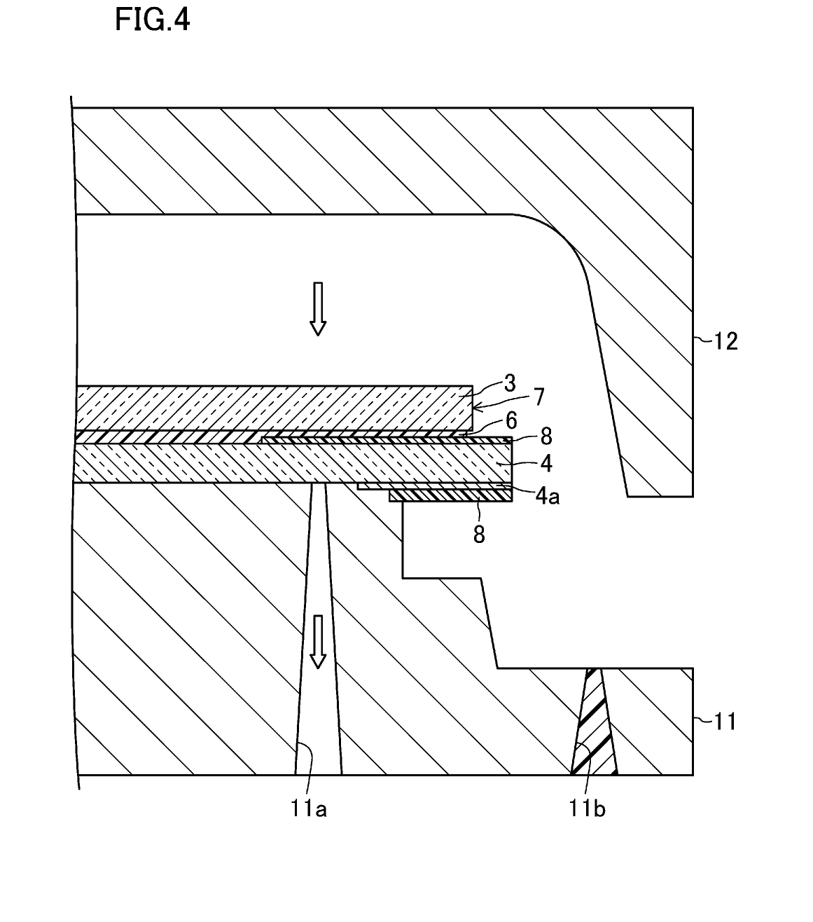

Then, referring to FIGS. 4-7, the process proceeds to an insert molding step. First, at a mounting step illustrated in FIG. 4, the glass panel 3 bonded to the touch panel 4 is mounted on a lower mold 11. The touch panel 4 is, at the rear surface thereof, held by suction through a suction hole 11a formed at the lower mold 11.

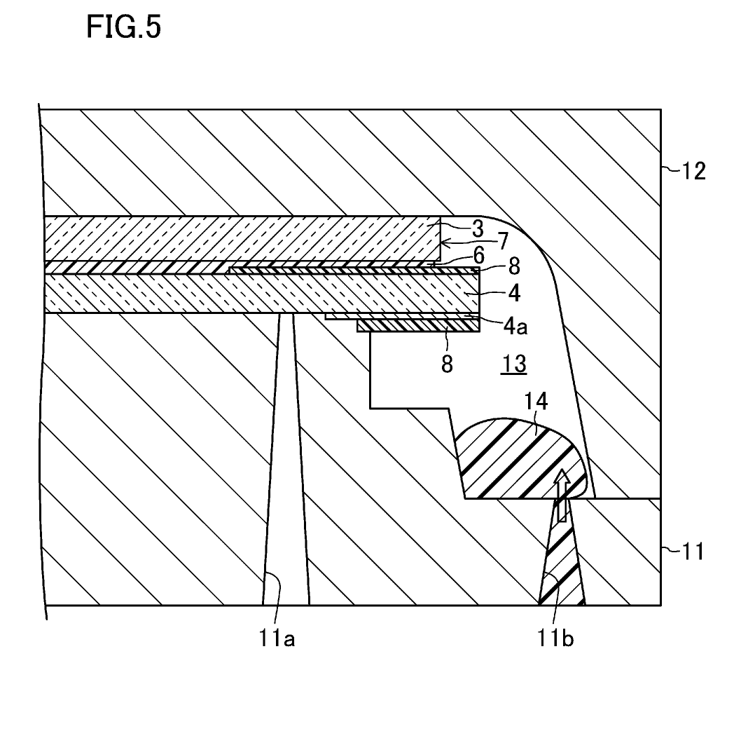

Next, at a mold clamping step illustrated in FIG. 5, the lower mold 11 and an upper mold 12 are clamped together. Then, at an injection step, melted resin 14 is injected into a cavity 13 through a gate 11b. For example, polycarbonate/acrylonitrile-butadiene-styrene blend (PC+ABS) resin is used as the resin 14 to be injected, considering compatibility with the decorative-printed coat 8.

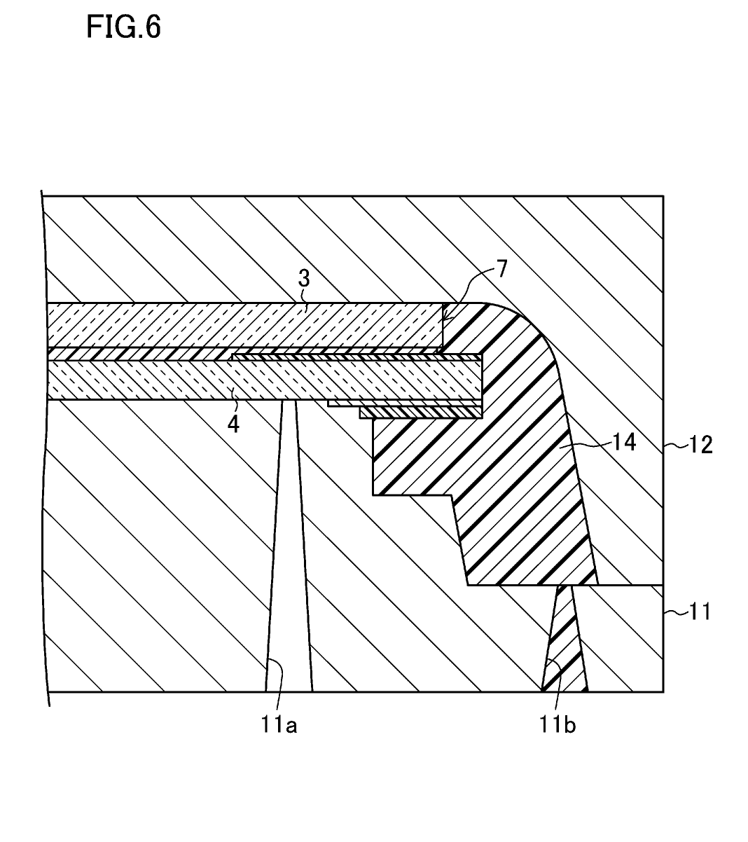

Then, referring to FIG. 6, the resin 14 flows into a corner space 7 formed between a protruding part of the touch panel 4 and a side surface of the glass panel 3. Subsequently, the resin 14 is cooled and cured.

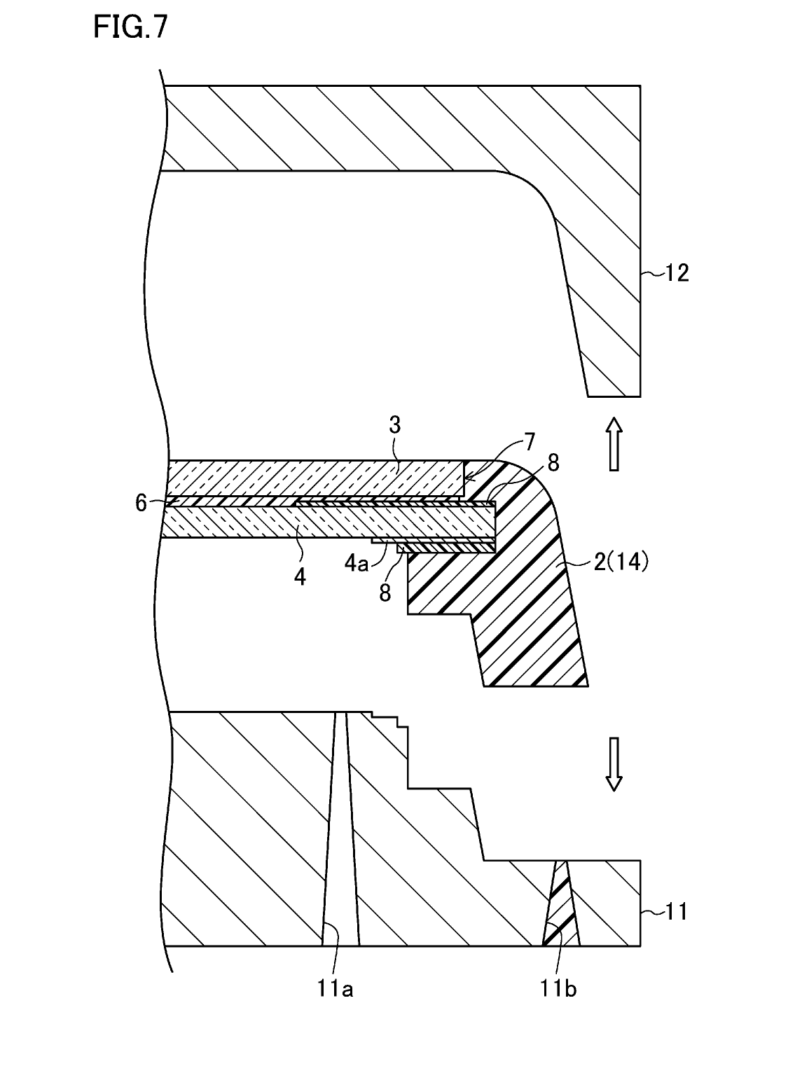

Next, referring to FIG. 7, at a mold detaching step, a housing 2 formed such that the glass panel 3 and the touch panel 4 are insert-molded together is detached. At this point, particular attention should be paid not to cause warpage, considering the difference in linear expansion coefficient between the glass and the resin 14.

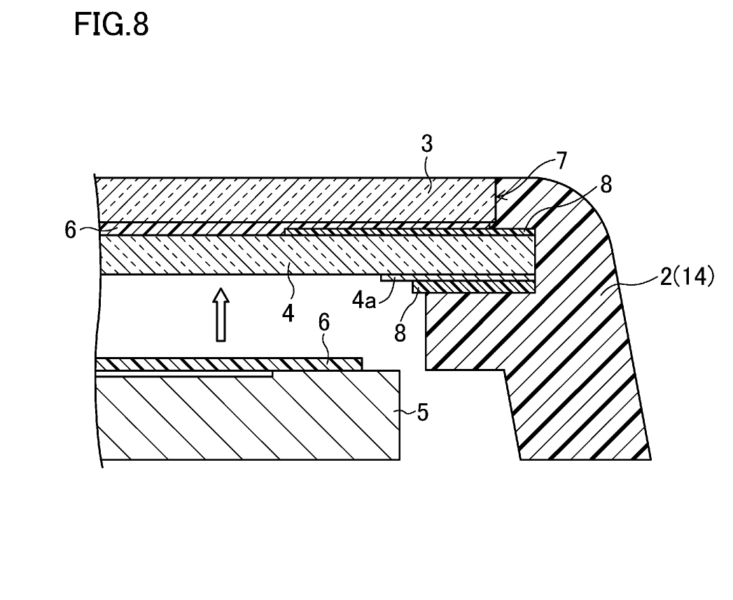

Finally, referring to FIG. 8, a liquid crystal display 5 is bonded to the rear surface of the touch panel 4 with the transparent optical adhesive tape 6. In the foregoing manner, the housing 2 including the glass panel 3, the touch panel 4, and the liquid crystal display 5 is formed as illustrated in FIG. 1.

As just described, the resin 14 is, by insert molding, injected into the corner space 7 formed between the glass panel 3 and the touch panel 4 bonded to the rear surface of the glass panel 3 and having a larger width. Such a simple method allows the resin 14 to exhibit a wedge effect, and therefore the glass panel 3 is not easily detached due to drop impact and torsional load. Moreover, since the wedge effect improves strength, a large bonding region required in conventional cases is not necessary, and the display area A can be expanded.

Further, the resin 14 exhibits the wedge effect not only in a width direction but also in a longitudinal direction, thereby further increasing the strength and expanding the display area A.

Thus, according to the mobile phone 1 of the present embodiment, the width of the touch panel 4 is set greater than that of the glass panel 3, and the touch panel 4 and the glass panel 3 are integrally formed with the housing 2 such that the corner space 7 formed between the protruding part of the touch panel 4 and the side surface of the glass panel 3 is covered by the resin forming the housing 2 in the state in which the touch panel 4 is bonded to the rear surface of the glass panel 3. Thus, while ensuring as large display area A as possible, the bonding strength between the glass panel 3 and the resin housing 2 can be ensured.

### Variations of First Embodiment

Referring to FIGS. 9A to 9C, there are three patterns of the difference in dimensions between the glass panel 3 and the touch panel 4.

First, in an example of the first embodiment illustrated in FIG. 9A, x1>x2 and y1>y2 are satisfied as described above. The touch panel 4 is larger than the glass panel 3 not only in the horizontal direction but also in the vertical direction. That is, a wedge effect exhibited by the entirety of the corner space 7 formed in a frame shape significantly improves bonding strength and waterproof properties.

In a first variation illustrated in FIG. 9B, x1>x2 and y1′>y2′ are satisfied, but no corner space 7 is formed on the upper side. Even in this case, a wedge effect significantly improves bonding strength and waterproof properties as compared to conventional cases.

In a second variation illustrated in FIG. 9C, x1>x2 is satisfied, but y1″ is equal to y2″. Although no corner space 7 is formed on the upper and lower sides, a wedge effect exhibited in the width direction by the corner space 7 extending in the vertical direction significantly improves bonding strength and waterproof properties as compared to conventional cases.

### Second Embodiment

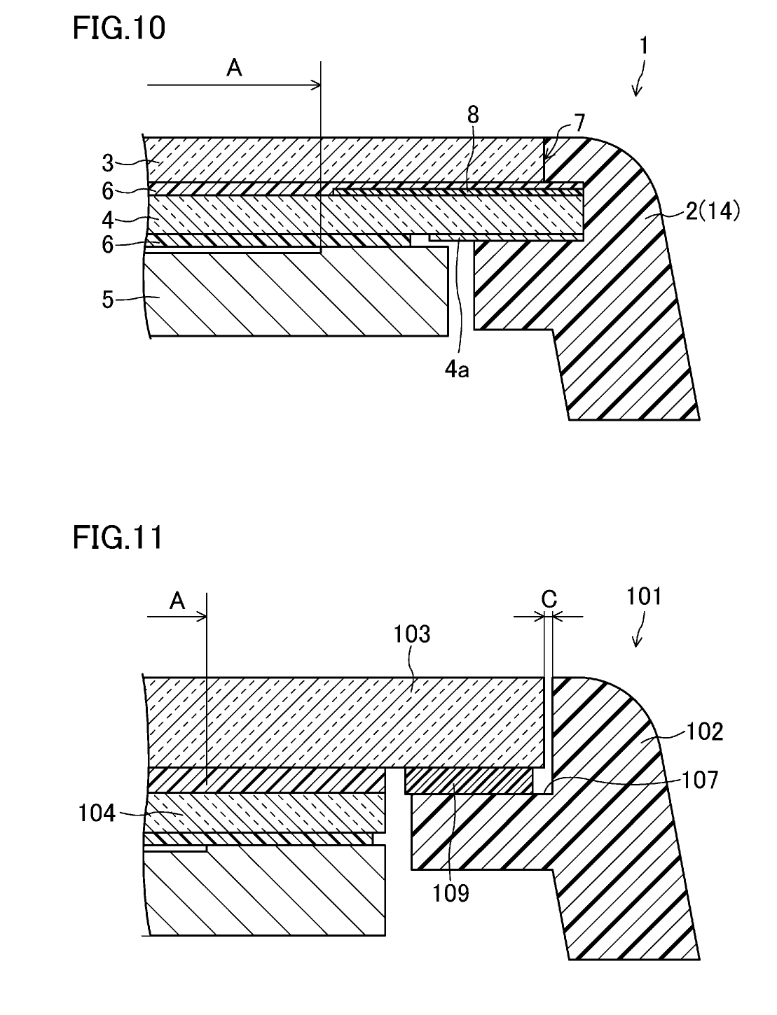

FIG. 10 illustrates a second embodiment of the present invention, and the second embodiment is different from the first embodiment in region of a touch panel 4 bonded to a transparent optical adhesive tape 6. Note that the same reference numerals as those shown in FIGS. 1 to 8 are used to represent equivalent elements in the present embodiment, and the description thereof will not be repeated.

That is, in the present embodiment, the transparent optical adhesive tape 6 bonding the touch panel 4 to a rear surface of a glass panel 3 is extended so as to cover across substantially the entirety of a protruding part of the touch panel 4, and is bonded to resin 14 (i.e., a housing 2).

Since the resin 14 and the touch panel 4 are also bonded together with the transparent optical adhesive tape 6 at a corner space 7, bonding strength is further improved. In addition, the flexibility of the transparent optical adhesive tape 6 significantly improves a waterproof effect.

Thus, in the present embodiment, bonding strength and waterproof properties can be further ensured even if a bonding area between the corner space 7 and the resin is narrowed due to expansion of a display area A.

### OTHER EMBODIMENTS

The foregoing embodiments of the present invention may have the following configurations.

That is, in the foregoing embodiments, the mobile terminal is the mobile phone 1. However, the mobile terminal may be personal handy-phone systems (PHSs), personal digital assistants (PDAs), smartphones, personal computers, mobile tools, electronic dictionaries, electronic calculators, game machines, etc as long as each of the foregoing includes a glass panel and a touch panel bonded to a rear side of the glass panel.

Note that the foregoing embodiments have been set forth merely for the purposes of preferred examples in nature, and are not intended to limit the scope, application, and use of the invention. Moreover, the techniques described in the foregoing embodiments can be combined together, and can be also combined into a new technique.

### INDUSTRIAL APPLICABILITY

As described above, the present invention is useful for a mobile terminal such as a mobile phone including a glass panel and a touch panel bonded to a rear side of the glass panel.

### DESCRIPTION OF REFERENCE CHARACTERS

1 Mobile Phone (Mobile Terminal)
2 Housing
3 Glass Panel
4 Touch Panel
4a Touch Panel Wiring Area
5 Liquid Crystal Display
6 Transparent Optical Adhesive Tape
7 Corner Space
8 Decorative-printed Coat
11 Lower Mold
11a Suction Hole
11b Gate
12 Upper Mold
13 Cavity
14 Resin

1. A mobile terminal comprising:
a glass panel; and
a touch panel provided on a rear side of the glass panel,
wherein a width of the touch panel is greater than that of the glass panel, and
in a state in which the touch panel is bonded to a rear surface of the glass panel, the touch panel and the glass panel are integrally molded with a housing such that a corner space formed between a protruding part of the touch panel and a side surface of the glass panel is covered by resin forming the housing.

2. The mobile terminal of claim 1, wherein
the resin covering the corner space and a touch panel wiring area overlap with each other as viewed from front.

3. The mobile terminal of claim 1, wherein
a transparent optical adhesive tape bonding the touch panel to the rear surface of the glass panel is extended to the protruding part of the touch panel, and is bonded to the resin.

4. The mobile terminal of claim 1, wherein
a length of the touch panel is greater than that of the glass panel, and
the touch panel and the glass panel are integrally molded with the housing such that a corner space formed between part of the touch panel protruding in a length direction and the side surface of the glass panel is also covered by the resin forming the housing.

5. The mobile terminal of claim 1, wherein
the touch panel further includes a glass plate, and
a ratio of a thickness of the glass plate to a thickness of the glass panel is about 1:1.

6. The mobile terminal of claim 1, wherein
a ratio of a length of the protruding part of the touch panel to the thickness of the glass panel is about 1:1.

7. A method for manufacturing a mobile terminal including a touch panel on a rear side of a glass panel, comprising:
a preparation step of preparing the glass panel and the touch panel having a width greater than that of the glass panel;
a bonding step of bonding the touch panel to a rear surface of the glass panel; and
an insert molding step of mounting the glass panel bonded to the touch panel on a mold, inserting resin into a corner space formed between a protruding part of the touch panel and a side surface of the glass panel, and insert-molding a housing out of the resin.
